(19) United States
(12) Patent Application Publication
(10) Pub. No.: US 2010/0290496 A1
(43) Pub. Date: Nov. 18, 2010

(54) NITRIDE SEMICONDUCTOR LASER DEVICE

(76) Inventors: Toru TAKAYAMA, Hyogo (JP); Tomoya Satoh, Hyogo (JP)

Correspondence Address: MCDERMOTT WILL & EMERY LLP, 600 13TH STREET, NW, WASHINGTON, DC, 20005-3096, US

(21) Appl. No.: 12/697,651

(22) Filed: Feb. 1, 2010

(30) Foreign Application Priority Data
May 13, 2009 (JP) 2009-116824

(51) Int. Cl. H01S 5/22; H01S 5/30; H01S 5/323

(52) U.S. Cl. 372/46.012

(57) ABSTRACT

A nitride semiconductor laser device includes: an active layer made of a nitride formed on a semiconductor substrate; a stripe-shaped ridge waveguide including a cladding layer having a ridge structure in its upper portion, formed on the active layer; a first current blocking layer transparent to light generated from the active layer, formed at least on a side face of the ridge waveguide; a second current blocking layer having light absorbency, formed on a flat portion of the cladding layer on each side of the ridge waveguide at a position spaced from the side face of the waveguide; and a third current blocking layer formed on the first and second current blocking layers, wherein ηg>η1, ηg>η2, and ηg<η3 are satisfied where η1, η2, η3, and ηg are respectively the heat expansion coefficients of the first, second, and third current blocking layers and gallium nitride.

### CROSS-REFERENCE TO RELATED APPLICATION

This application claims priority to Japanese Patent Application No. 2009-116824 filed on May 13, 2009, the disclosure of which including the specification, the drawings, and the claims is hereby incorporated by reference in its entirety.

### BACKGROUND

The present disclosure relates to a nitride semiconductor laser device, and more particularly to a nitride semiconductor laser device having a ridge structure.

Blue semiconductor laser devices have been used as light sources for recording/reproduction to/from high-density optical disc systems such as a disc storage device and a Blu-ray Disc (registered trademark). As blue semiconductor laser devices, semiconductor laser devices using III-V group nitrides are used.

When used as the light source for an optical disc system, a blue semiconductor laser device is requested to exhibit properties excellent in linearity with no kink occurring in current-light output characteristics even at a high output of 300 mW or more that is required for quad-speed or faster recording. Moreover, to record/reproduce information to/from an optical disc with high precision, a far field pattern (FFP) suitable for the laser light condensing property of a lens is requested. To enhance the property of condensing laser light on an optical disc, the luminous diameter of a near field pattern (NFP) as the light distribution propagating in a waveguide is preferably small. Assume herein that the direction parallel to an active layer is the horizontal direction and the direction perpendicular to the active layer is the vertical direction. When the full width at half maximum of the NFP in the horizontal direction is small, for example, the full width at half maximum of the FFP is large. Hence, a horizontal spread angle of 8° or more is desired as the full width at half maximum of the FFP in the horizontal direction.

At present, as a blue semiconductor laser device, a ridge nitride semiconductor laser device having a stripe-shaped ridge structure extending along the length of the cavity is widely known. In this structure, normally, a current blocking layer made of a semiconductor or a dielectric is formed on the side faces of the ridge portion, and the difference (ΔN) in effective refractive index between the outside and inside of the ridge portion can be controlled using the distance (dp) between the current blocking layer in the regions outside the ridge portion and an active layer. The width of the ridge portion may also be used as a parameter, to control the full width at half maximum of laser light propagating in the waveguide. In this way, using the ridge structure, the light distribution can be controlled with the ridge width and dp, to obtain a desired light distribution. Hence, this structure has been widely used as a structure of semiconductor laser devices for optical discs.

To increase the horizontal spread angle of the FFP, it is effective to increase ΔN to strengthen confinement of the light distribution within the ridge portion, or reduce the width of the ridge portion to reduce the width of the light distribution directly. However, when ΔN is increased, laser oscillation in a horizontal high-order transverse mode occurs, causing a kink in the current-light output characteristics. To prevent this, the width of the ridge portion may be reduced to cut off the horizontal high-order transverse mode. However, reduction in ridge width will lead to increase in device resistance because the drive current for the semiconductor laser device is narrowed by the ridge portion before being fed into the active layer. Increase in device resistance also results in increase in drive voltage. Hence, reducing the width of the ridge portion is undesirable because this causes heat generation due to increased power consumption and limitation of the supply voltage for a laser drive circuit.

A nitride semiconductor laser device that can enhance the kink level without reducing the width of the ridge portion is described in Japanese Patent Publication No. 2002-314197. FIG. 24 shows a nitride semiconductor laser device as the first conventional example that can enhance the kink level without reducing the ridge width.

As shown in FIG. 24, in the nitride semiconductor laser device of the first conventional example, an active layer 201 is formed on a lower cladding layer 200, an upper cladding layer 202 having a ridge structure is formed on the active layer 201, and a contact layer 206 is formed on the top of the ridge portion of the upper cladding layer 202. An insulating film 203 substantially transparent to the oscillation wavelength is formed on the side faces of the upper cladding layer 202 and the contact layer 206 and on the flat portions of the upper cladding layer 202. Absorption layers 204 and 207 that absorb laser light are formed on the insulating film 203. An electrode film 205 is formed covering the insulating film 203, the absorption layers 204 and 207, and the contact layer 206. The thicknesses of the insulation film 203 and the absorption layers 204 and 207 are set so that the absorption coefficient in a horizontal high-order transverse mode is larger than that in a horizontal fundamental transverse mode.

With the structure described above, the amount of increase in waveguide loss in the horizontal high-order transverse mode can be made larger than that in the horizontal fundamental transverse mode, so that the oscillation in the horizontal high-order transverse mode can be suppressed. Hence, occurrence of a kink in the current-light output characteristics can be suppressed without reducing the ridge width.

However, the configuration shown in FIG. 24 also increases the waveguide loss in the horizontal fundamental transverse mode. As a result, the slope efficiency in the current-light output characteristics decreases, and this increases the operating current. When further high output is planned in the future to achieve higher-speed recording operation, the operating current and the operating voltage will increase with this conventional structure, resulting in increase in power consumption and hence degradation in device reliability.

To address the above problem, a nitride semiconductor laser device that can suppress increase in waveguide loss in a horizontal fundamental transverse mode is described in Japanese Patent Publication No. 2003-198065. FIG. 25 shows a nitride semiconductor laser device as the second conventional example that can suppress increase in waveguide loss in the horizontal fundamental transverse mode.

As shown in FIG. 25, an n-type GaN layer 312, an n-type anti-crack layer 313, an n-type cladding layer 314, an n-type guide layer 315, an active layer 316, a p-type barrier layer 317, and a p-type guide layer 318 are sequentially formed on a gallium nitride (GaN) substrate 311. A p-type cladding layer 319 having a ridge structure is formed on the p-type guide layer 318, and a contact layer 320 is formed on the top of the ridge portion of the p-type cladding layer 319. A light absorption layer 322 is formed to extend in the light resonance direction on the flat portions of the p-type cladding layer 319 at a position spaced from each side face of the bottom of the ridge portion by a distance of 0.3 μm or more. A current blocking layer 321 made of a dielectric substantially transparent to laser oscillated light for confining the laser oscillated light is formed covering the side faces of the ridge portion constructed of the p-type cladding layer 319 and the contact layer 320 and the light absorption layer 322. A p-type electrode 323 is formed covering the contact layer 320 and the current blocking layer 321, and an n-type electrode 310 is formed on the surface of the GaN substrate 311 opposite to the surface on which the n-type GaN layer 312 is formed.

With the structure of the nitride semiconductor laser device of the second conventional example shown in FIG. 25, in which the light absorption layer 322 is not formed on the side faces of the ridge portion, increase in waveguide loss in the horizontal fundamental transverse mode can be suppressed. Also, since the light distribution in a horizontal high-order transverse mode spreads horizontally to the outside of the ridge portion more largely than that in the horizontal fundamental transverse mode, it is possible to increase the increase in waveguide loss in the horizontal high-order transverse mode compared with that in the horizontal fundamental transverse mode. In addition, since part of spontaneously emitted light can be absorbed by the light absorption layer 322, troubles such as noise and difficulty in control related to spontaneously emitted light can be reduced.

When amorphous silicon (Si) is used for the light absorption layer 322, the distance between each side face of the ridge portion and the light absorption layer 322 may be set at 0.3 μm, to obtain the greatest effect of suppressing oscillation in the horizontal high-order transverse mode.

### SUMMARY

However, the nitride semiconductor laser device of the second conventional example shown in FIG. 25 has the following problem.

Amorphous silicon (Si) is often used as a light absorbent material for blue laser light for the reason of easiness of fabrication. The thermal expansion coefficient of amorphous Si is 0.6×10⁻⁶/k or less, and that of GaN as a nitride material is 5.6×10⁻⁶/k. Therefore, in the device fabrication process, when the temperature is lowered from a high-temperature state during formation of the light absorption layer 322 to room temperature, a stress may be generated in the light absorption layer 322 and a portion of the nitride material constituting the p-type cladding layer 319 near the ridge bottom due to the difference in thermal expansion coefficient between the two layers.

The nitride material has a wurtzite (WZ) crystal structure. Therefore, if a stress is generated in the crystal distorting the crystal structure, the symmetry of an array of III-group atoms and V-group atoms is lost, and as a result, a large electric field is generated inside the crystal due to the piezoelectric effect. With this internal electric field, the atom arrangement is further deformed, changing the electron orbit in the crystal and hence greatly changing the dielectric constant. The change in dielectric constant leads to change in refractive index. The influence of the stress-caused crystal distortion on the change in refractive index in the nitride material is greater than that in a semiconductor material having a zincblende (ZB) crystal structure typified by gallium arsenide (GaAs).

When amorphous Si is used for the light absorption layer 322, the refractive index of a portion of the p-type cladding layer 319 located between a region of the current blocking layer 321 near the ridge bottom and the active layer 316 increases. As a result, the light distribution deforms to spread to the outside of the ridge portion due to the stress-caused change in refractive index. This increases the waveguide loss in the horizontal fundamental transverse mode by the optical absorption layer 322, leading to decrease in slope efficiency and increase in operating current value.

In view of the above, in the configuration shown in FIG. 25, when the light absorption layer 322 is formed to be close to the side faces of the ridge portion for suppressing laser oscillation in the horizontal high-order transverse mode, the waveguide loss in the horizontal fundamental transverse mode increases. This increases the oscillation threshold current value and the operating current value, and hence increases the power consumption of the device, resulting in degradation in reliability. Also, the light distribution deforms to spread to the outside of the ridge portion, resulting in reducing the horizontal spread angle of the FFP. In this case, to obtain a desired FFP horizontal spread angle, it is necessary to reduce the width of the ridge portion, or set structural parameters to obtain a larger ΔN value, as described above. This will lead to increase in element resistance and decrease in kink level.

As described above, the nitride semiconductor laser device of the second conventional example fails to improve the kink level and obtain a desired FFP horizontal spread angle characteristic as wide as 8° or more without causing increase in waveguide loss in the horizontal fundamental transverse mode and increase in device resistance.

In view of the above problem, it is an object of the present invention to provide a nitride semiconductor laser device in which a stress generated in a cladding layer is reduced to improve the slope efficiency and the kink level and hence a FFP with no disturbance is presented.

To attain the object described above, a nitride semiconductor laser device according to the present invention is configured to have a third current blocking layer larger in thermal expansion coefficient than gallium arsenide, which is formed on a first current blocking layer transparent to light generated from an active layer and a second current blocking layer as an optical absorption layer.

Specifically, the nitride semiconductor laser device of the present invention includes: an active layer made of a nitride formed on a semiconductor substrate; a stripe-shaped ridge waveguide including a cladding layer having a ridge structure in its upper portion, formed on the active layer; a first current blocking layer transparent to light generated from the active layer, formed at least on a side face of the ridge waveguide; a second current blocking layer having light absorbency, formed on a flat portion of the cladding layer on each side of the ridge waveguide at a position spaced from the side face of the ridge waveguide, and a third current blocking layer formed on the first current blocking layer and the second current blocking layer, wherein ηg>η1, ηg>η2, and ηg<η3 are satisfied where η1, η2, and η3 are respectively the heat expansion coefficients of the first, second, and third current blocking layers, and ηg is the heat expansion coefficient of gallium nitride.

According to the nitride semiconductor laser device of the present invention, the stress generated in the cladding layer made of a nitride material formed between the first current blocking layer and the active layer can be reduced. As a result, the change in the refractive index of the cladding layer having the ridge portion can be reduced. Hence, variations in FFP caused by variations in fabrication process steps for the first current blocking layer and the second current blocking layer can be suppressed. A desired light distribution can therefore be achieved with high precision. Moreover, the light distribution can be prevented from largely spreading to the outside of the ridge portion under the influence of a distortion of the crystal structure. Accordingly, since the waveguide loss in the horizontal fundamental transverse mode can be prevented from increasing, stable and high slope efficiency can be obtained.

In the nitride semiconductor laser device of the present invention, preferably, the first current blocking layer is not formed on a top portion of the side face of the ridge waveguide.

With the above configuration, the thickness of the first current blocking layer formed on each side face of the ridge portion in the direction normal to the substrate is reduced, and this can reduce the stress exerted on the cladding layer at each bottom edge of the ridge portion caused by the difference in heat expansion coefficient between the first current blocking layer and the nitride material constituting the waveguide. As a result, the change in refractive index caused by the stress exerted on the cladding layer at each bottom edge of the ridge portion can be reduced, and hence variations in FFP caused by variations in fabrication process steps for the first current blocking layer can be further suppressed. A desired light distribution can therefore be achieved with further high precision. Moreover, the light distribution can be prevented from largely spreading to the outside of the ridge portion under the influence of a distortion of the crystal structure.

In the nitride semiconductor laser device of the present invention, preferably, Rf<Rr and A1f<A1r are satisfied where Rf and Rr are respectively the end facet reflectances on the front end facet side and rear end facet side of the cavity, and A1f and A1r are respectively the distances from the side face of the ridge waveguide to the second block layer at the front end facet and the rear end facet.

With the above configuration, since the distance between each side face of the ridge waveguide and the second current blocking layer is small on the front end facet side where the light density is high, the waveguide loss in the horizontal high-order transverse mode increases. Furthermore, scattered light from the waveguide can be absorbed by the second current blocking layer on the front end facet side. As a result, a good unimodial FFP can be obtained, and occurrence of a kink in the current-light output characteristics can be suppressed.

In the case described above, preferably, Wf>Wr is satisfied where Wf and Wr are respectively the widths of the ridge waveguide on the front end facet side and rear end facet side of the cavity.

With the above configuration, since a larger amount of current can be injected on the front end facet side where the light density is high, the efficiency of converting the current to light improves. As the width of the ridge portion is smaller, the spread of the light distribution to the outside of the ridge portion is larger. Therefore, the distance between the second current blocking layer and each bottom edge of the ridge portion on the rear end facet side where the ridge width is small is made larger than the distance thereof on the front end facet side. With this configuration, it is possible to increase the difference in waveguide loss between the horizontal fundamental transverse mode and the horizontal high-order transverse mode while reducing the light absorption loss in the horizontal fundamental transverse mode by the second current blocking layer 19. Hence, the emission efficiency and the kink level can be improved.

In the nitride semiconductor laser device of the present invention, the second current blocking layer is preferably formed on the first current blocking layer.

With the above configuration, the waveguide loss in the horizontal fundamental transverse mode incurred by the second current blocking layer can be controlled with high precision.

In the nitride semiconductor laser device of the present invention, the second current blocking layer is preferably formed on the cladding layer to be in contact with the cladding layer.

With the above configuration, the waveguide loss in the horizontal high-order transverse mode by the second current blocking layer can be increased. As a result, oscillation in the horizontal high-order transverse mode can be efficiently suppressed.

In the nitride semiconductor laser device of the present invention, the second current blocking layer is preferably formed on at least one of cavity end facets formed at both ends of the ridge waveguide.

With the above configuration, it is possible to increase the waveguide loss in the horizontal high-order transverse mode while suppressing increase in waveguide loss in the horizontal fundamental transverse mode. Hence, the oscillation threshold current value can be reduced, the slope efficiency can be improved, and the kink level in the current-light output characteristics can be improved. Also, with formation of the light absorption region on the front end facet side from which laser light is extracted, scattered light and spontaneously emitted light from the waveguide are absorbed on the front end facet side and removed. Therefore, a good FFP shape can be obtained. Moreover, laser oscillation in the horizontal high-order mode can be suppressed without reducing the width of the ridge portion. Therefore, occurrence of a kink in the current-light output characteristics can be prevented without causing increase in device resistance.

As described above, in the nitride semiconductor laser device of the present invention, it is possible to increase the waveguide loss in the horizontal high-order transverse mode while suppressing increase in waveguide loss in the horizontal fundamental transverse mode. This reduces the oscillation threshold current value and improves the slope efficiency. Accordingly, the kink level in the current-light output characteristics can be improved, and hence a good FFP shape can be obtained.

### BRIEF DESCRIPTION OF THE DRAWINGS

FIG. 1 is a cross-sectional view of a nitride semiconductor laser device having two current blocking layers as a first comparison example.

FIG. 2A is a graph showing calculation results of a waveguide loss in a horizontal fundamental transverse mode with d1 and d2 shown in FIG. 1 as parameters.

FIG. 2B is a graph showing calculation results of a waveguide loss in a horizontal high-order transverse mode with d1 and d2 shown in FIG. 1 as parameters.

FIG. 3 is a cross-sectional view of a nitride semiconductor laser device of a first illustrative embodiment.

FIG. 4 is a cross-sectional view of a nitride semiconductor laser device having no third current blocking layer as a second comparison example.

FIG. 5 is a graph showing calculation results of a stress in a p-type cladding layer in the nitride semiconductor laser device of the first illustrative embodiment.

FIG. 6 is a graph showing calculation results of a stress in a p-type cladding layer in the nitride semiconductor laser device of the second comparative example.

FIG. 7A is a graph showing NFP distribution shapes in the horizontal fundamental transverse mode in the nitride semiconductor laser devices of the first illustrative embodiment (solid line) and the second comparison example (broken line).

FIG. 7B is a graph showing NFP distribution shapes in the horizontal high-order transverse mode in the nitride semiconductor laser devices of the first illustrative embodiment (solid line) and the second comparison example (broken line).

FIG. 8 is a graph showing the relationship between the FFP horizontal spread angle and the thickness of a third current blocking layer in the nitride semiconductor laser device of the first illustrative embodiment.

FIG. 9 is a plan view of the nitride semiconductor laser device of the first illustrative embodiment.

FIGS. 10A to 10D are graphs showing the relationship between the waveguide losses in the horizontal fundamental transverse mode and the horizontal high-order transverse mode and the distance from a side face of a ridge portion to a second current blocking layer in the nitride semiconductor laser device of the first illustrative embodiment.

FIG. 11 is a plan view of a nitride semiconductor laser device of a first variation of the first illustrative embodiment.

FIG. 12 is a plan view of a nitride semiconductor laser device of a second variation of the first illustrative embodiment.

FIG. 13 is a plan view of a nitride semiconductor laser device of a third variation of the first illustrative embodiment.

FIG. 14 is a plan view of a nitride semiconductor laser device of a fourth variation of the first illustrative embodiment.

FIG. 15 is a plan view of a nitride semiconductor laser device of a fifth variation of the first illustrative embodiment.

FIG. 16 is a plan view of a nitride semiconductor laser device of a sixth variation of the first illustrative embodiment.

FIG. 17 is a plan view of a nitride semiconductor laser device of a seventh variation of the first illustrative embodiment.

FIG. 18 is a plan view of a nitride semiconductor laser device of an eighth variation of the first illustrative embodiment.

FIG. 19 is a plan view of a nitride semiconductor laser device of a ninth variation of the first illustrative embodiment.

FIG. 20 is a plan view of a nitride semiconductor laser device of a tenth variation of the first illustrative embodiment.

FIG. 21 is a cross-sectional view of a nitride semiconductor laser device of a second illustrative embodiment.

FIG. 22 is a graph showing the relationship between the waveguide losses in the horizontal fundamental transverse mode and the horizontal high-order transverse mode and the distance from a side face of a ridge portion to a second current blocking layer in the nitride semiconductor laser device of the second illustrative embodiment.

FIG. 23 is a graph showing measurement results of the current-light output characteristics of the nitride semiconductor laser devices of the first illustrative embodiment, the second illustrative embodiment, and the first comparative example.

FIG. 24 is a cross-sectional view of a nitride semiconductor laser device of a first conventional example.

FIG. 25 is a cross-sectional view of a nitride semiconductor laser device of a second conventional example.

### DETAILED DESCRIPTION

Nitride semiconductor laser devices according to the present disclosure will be described with reference to the drawings.

### First Comparative Example

First, the first comparative example in this disclosure will be described.

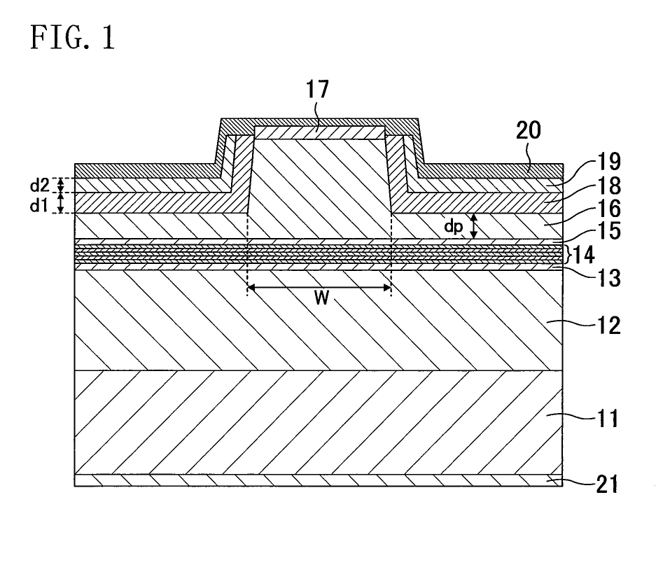

As shown in FIG. 1, an n-type cladding layer 12 made of aluminum gallium nitride (AlGaN) having a thickness of 2.5 μm, an n-type guide layer 13 made of AlGaN having a thickness of 86 nm, a quantum well active layer 14 made of an InGaN material, and a p-type electron block layer 15 made of AlGaN having a thickness of 10 nm are formed sequentially on a semiconductor substrate 11 made of gallium nitride (GaN). On the p-type electron block layer 15, formed is a p-type cladding layer 16 made of AlGaN, which has a ridge structure and has a thickness of 0.5 μm in the ridge portion. A p-type contact layer 17 made of GaN having a thickness of 0.1 μm is formed on the top of the ridge portion of the p-type cladding layer 16. A first current blocking layer 18 transparent to light generated in the quantum well active layer 14 is formed on the side faces of the ridge portion of the p-type cladding layer 16 and on the flat portions thereof. A second current blocking layer 19 having light absorbency is formed on the first current blocking layer 18. A p-type electrode 20 is formed covering the p-type contact layer 17, the first current blocking layer 18, and the second current blocking layer 19, and an n-type electrode 21 is formed on the surface of the semiconductor substrate 11 opposite to the surface on which the n-type cladding layer 12 is formed. Assume that the width (W) of the ridge portion is 1.4 μm, and that the thicknesses of the first and second current blocking layers 18 and 19 are respectively denoted by d1 and d2 and the thickness of the flat portions of the p-type cladding layer 16 by dp.

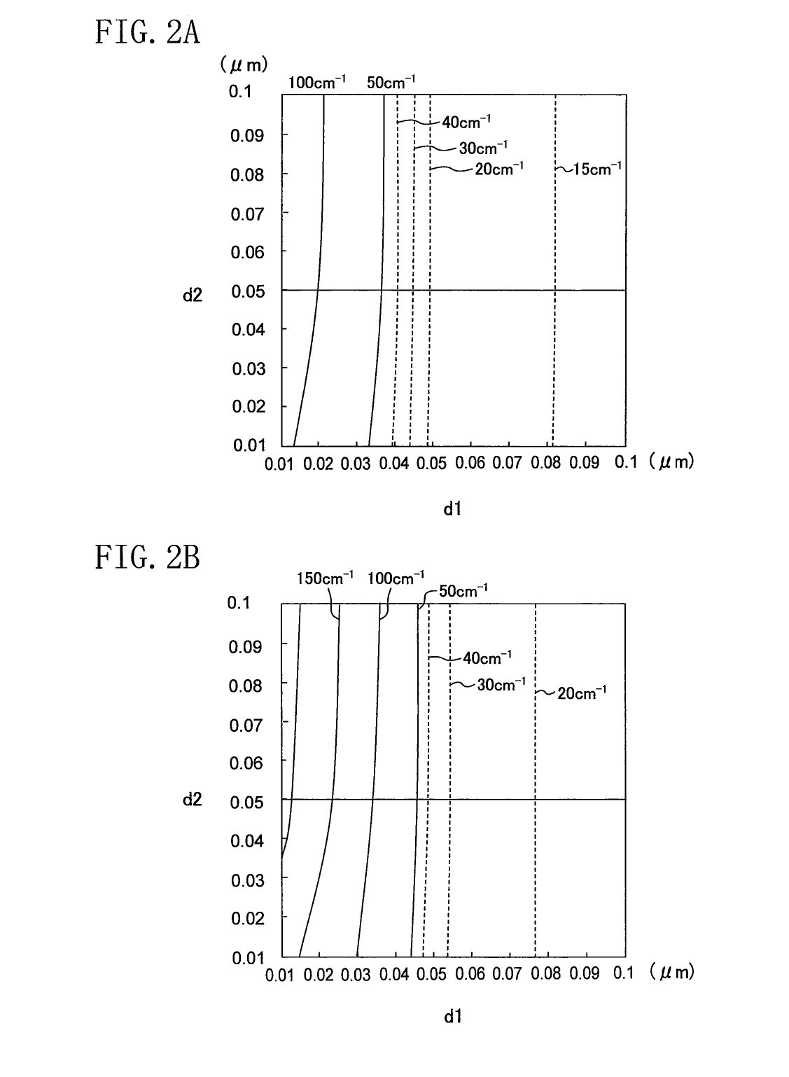

As shown in FIGS. 2A and 2B, as d1 is larger, both the waveguide loss (α0) in a horizontal fundamental (0-order) transverse mode and the waveguide loss (α1) in a horizontal high-order (1st-order) transverse mode are smaller. This is because as d1 becomes larger, the proportion of light entering the second current blocking layer 19 having light absorbency shown in FIG. 1 becomes smaller, thereby reducing the light absorption loss. Also, as d2 is larger, the waveguide loss increases. However, when the thickness is 0.05 μm or more, both the waveguide losses α0 and α1 depend on the magnitude of d1, hardly depending on the magnitude of d2. This is because, since the light distribution of laser light entering the second current blocking layer 19 is within the thickness of 0.05 μm, the light is attenuated by absorption and hence does not substantially exist in the region exceeding this thickness.

The waveguide losses can be reduced by increasing d1 as described above. To improve the kink level in the current-light output characteristics, however, it is necessary to suppress oscillation in the horizontal high-order transverse mode. To attain this, the waveguide loss α1 in the horizontal high-order transverse mode may be increased, to suppress oscillation in the high-order transverse mode. However, if d1 is simply reduced to increase α1, α0 will also increase. Hence, in oscillation in the fundamental transverse mode, the oscillation threshold current value will increase, reducing the slope efficiency in the current-light output characteristics. As a result, the operating current value will increase, causing degradation in reliability. Accordingly, to improve the kink level without causing decrease in slope efficiency, it is necessary to increase α1 while reducing α0 as much as possible.

The cavity length of a high-output nitride semiconductor laser device is set at 700 μm or more, and the front and rear end facets of the cavity are coated with a dielectric film to give reflectances of 10% or less and 90% or less, respectively, thereby ensuring high slope efficiency. The mirror loss αm of a semiconductor laser device is expressed by

αm=(½L)Logₑ(1/RfRr) (1)

where Rf, Rr and L are respectively the front reflectance, the rear reflectance, and the cavity length. At this time, the slope efficiency Se of the semiconductor laser device is expressed by

Se=ηdηi{αm/(αi+αm)} (2)

where ηd, ηi, and αi are respectively the light extraction efficiency from the front end facet, the internal quantum efficiency, and the waveguide loss. The waveguide loss αi is given by α0 for the horizontal fundamental transverse mode and α1 for the horizontal high-order transverse mode. From Equation (1), the mirror loss αm of the semiconductor laser device of which the front and rear end facets are coated with a dielectric film to give reflectances of 10% and 90%, respectively, is 17.2 cm⁻¹ when the cavity length L is 700 μm. The mirror loss αm decreases with increase of the cavity length L: it is 15 cm⁻¹ when the cavity length L is 800 μm, 12 cm⁻¹ when the cavity length L is 1000 μm, and 8 cm⁻¹ when the cavity length L is 1500 μm.

From Equation (2), it is found that the slope efficiency Se is proportional to the ratio of the mirror loss αm to the entire loss of the cavity (=αi+αm). Hence, the slope efficiency Se will decrease unless the device is fabricated so that the waveguide loss αi is small compared with the mirror loss αm. As described above, the mirror loss αm of a high-output nitride blue laser device is roughly in the range of 17.2 cm⁻¹ to 8 cm⁻¹ when the cavity length L is in the range of 700 μm to 1500 μm. In particular, the cavity length L is set in the range of 800 μm to 1000 μm for a high-output nitride semiconductor laser device having an output of about 300 mW to about 400 mW, and the mirror loss αm in this cavity length range is roughly in the range of 15 cm⁻¹ to 12 cm⁻¹. Accordingly, unless the waveguide loss α0 in the horizontal fundamental transverse mode is set at 15 cm⁻¹ or less, the increase in waveguide loss will increase the amount of decrease of the slope efficiency Se. To set α0 at 15 cm⁻¹ or less, d1 should be 0.081 μm or more as shown in FIG. 2A. At this time, when d2 is set at 0.05 μm or more as described above, α1 is 20 cm⁻¹ or less. Hence, it is found from the calculation results in FIGS. 2A and 2B that the difference between α1 and α0 (Δα=α1−α0) is only about 5 cm⁻¹.

When a semiconductor laser is subjected to high-output operation, implanted carriers are lost due to emission recombination under strong stimulated emission in an active layer portion in the center of a near field pattern (NFP) where the light density is high. Therefore, the operating carrier density in the active layer portion corresponding to the center of the light distribution is relatively lower than that in its flanking regions, causing spatial hole burning of carriers in which a horizontally concave shape is formed. When spatial hole burning of carriers occurs, the overlap between the shape of the active layer carrier distribution and the light distribution corresponding to the high-order transverse mode increases, and this increases the mode gain of the horizontal high-order transverse mode. Also, when the device is subjected to high-temperature, high-output operation, the temperature of the device rises increasing the refractive index of the ridge portion. This increases ΔN, and hence the horizontal high-order transverse mode becomes less easy to be cut off. Therefore, if Δα is small, oscillation in the horizontal high-order transverse mode will occur in high-temperature, high-output operation, generating a kink. Accordingly, in the configuration shown in FIG. 1, when setting is made to give Δα as large as possible and α0 of 15 cm⁻¹, the waveguide loss in the horizontal high-order transverse mode cannot be sufficiently increased. Hence, in high-temperature operation at 85° C., a sufficiently large effect of suppressing kink generation cannot be obtained. A kink is therefore generated in high-output operation of 300 mW or more. To prevent oscillation in the horizontal high-order transverse mode during high-temperature, high-output operation, α1 must be larger than α0 by at least 10 cm⁻¹ or more, preferably 20 cm⁻¹ or more.

When d1 is reduced to increase the waveguide loss α1 in the horizontal high-order transverse mode for suppressing oscillation in the horizontal high-order transverse mode, α0 also increases, and this reduces the slope efficiency.

For the reason described above, the double-layer current block structure as shown in FIG. 1 finds difficulty in implementing such a waveguide that serves as a low-loss waveguide for the horizontal fundamental transverse mode and can suppress oscillation in the horizontal high-order transverse mode stably even in high-temperature, high-output operation for the horizontal high-order transverse mode. Moreover, when Si-based materials such as amorphous silicon (Si) having a heat expansion coefficient of 0.6×10⁻⁶/K and silicon dioxide (SiO₂) having a heat expansion coefficient of 0.6×10⁻⁶/K to 0.9×10⁻⁶/K are used for the first current blocking layer 18 and the second current blocking layer 19, the heat expansion coefficient of the block layers is small compared with that of GaN, which is 5.6×10⁻⁶/K. Therefore, a stress is generated between the first current blocking layer 18 and the ridge portion of the p-type cladding layer 16 due to the difference in heat expansion. Specifically, a compressive stress is generated in the plane parallel to the active layer in regions near the bottom edges of the ridge portion, causing a distortion in the crystal structure. When a crystal structure is distorted, the refractive index of the distorted portions changes. Therefore, the refractive index of the regions near the bottom edges of the ridge portion of the p-type cladding layer 16 increases due to a compressive stress. As a result, the light distribution propagating in the waveguide fails to have a desired shape, spreading in the horizontal direction. Hence, when a Si-based material is used for a current blocking layer of a nitride semiconductor laser device, the NFP tends to spread in the horizontal direction, and as a result, the far field pattern (FFP) in the horizontal direction will be smaller than a desired value. For this reason, to obtain a desired FFP horizontal spread angle of 8° or more, the width (W) of the ridge portion must be reduced, or the thickness (dp) of the flat portions of the p-type cladding layer 16 must be reduced, to increase the difference (ΔN) in effective refractive index between the inside and outside of the ridge portion. However, as W is smaller, the series resistance of the device increases, increasing the operating voltage. Also, as dp is smaller, the stress caused by the difference in heat expansion coefficient also affects the active layer, causing occurrence of a lattice defect and hence degradation in reliability.

### First Illustrative Embodiment

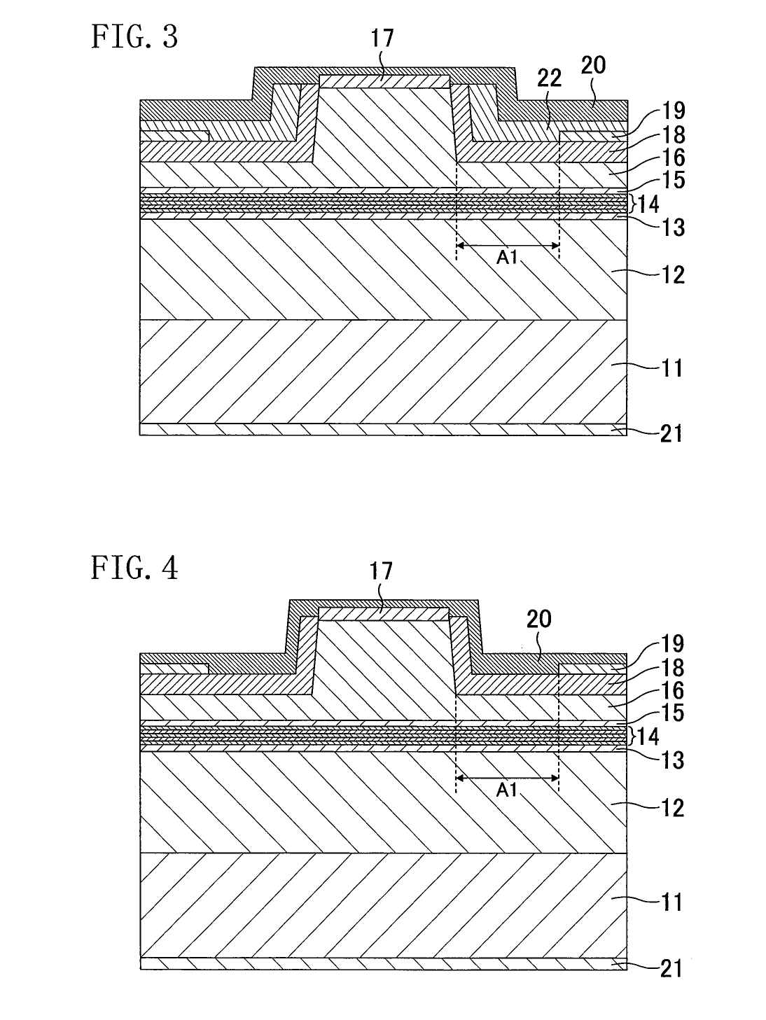

The first illustrative embodiment will be described with reference to FIG. 3.

As shown in FIG. 3, an n-type cladding layer 12 made of AlGaN having a thickness of 2.5 μm, an n-type guide layer 13 made of AlGaN having a thickness of 86 nm, a quantum well active layer 14 made of an InGaN material, and a p-type electron block layer 15 made of AlGaN having a thickness of 10 nm are formed sequentially on a semiconductor substrate 11 made of GaN. On the p-type electron block layer 15, formed is a p-type cladding layer 16 made of AlGaN, which has a ridge structure and has a thickness of 0.5 μm in the ridge portion. A p-type contact layer 17 made of GaN having a thickness of 0.1 μm is formed on the top of the ridge portion of the p-type cladding layer 16. A first current blocking layer 18 made of SiO₂ transparent to light generated in the quantum well active layer 14 is formed on the side faces of the ridge portion of the p-type cladding layer 16 and on the flat portions thereof. A second current blocking layer 19 made of amorphous Si having light absorbency is formed on the flat portions of the first current blocking layer 18 at a position spaced from each side face of the bottom of the ridge portion of the p-type cladding layer 16 by distance A1. On the first current blocking layer 18 and the second current blocking layer 19, formed is a third current blocking layer 22 made of zirconium dioxide (ZrO₂) having a heat expansion coefficient of 8.0×10⁻⁶/K to 11.5×10⁻⁶/K. A p-type electrode 20 is formed covering the p-type contact layer 17, the first current blocking layer 18, and the third current blocking layer 22, and an n-type electrode 21 is formed on the surface of the semiconductor substrate 11 opposite to the surface on which the n-type cladding layer 12 is formed.

Unlike the first comparative example shown in FIG. 1, the second current blocking layer 19 is spaced from each side face of the bottom of the ridge portion by the distance A1. Therefore, the light absorption loss in the horizontal fundamental transverse mode by the second current blocking layer 19 can be reduced, and hence the waveguide loss can be reduced. Also, since the heat expansion coefficient of ZrO₂ is larger than that of GaN, the provision of the third current blocking layer 22 can reduce the stress generated in the regions of the p-type cladding layer 16 near the bottom edges of the ridge portion due to the difference in heat expansion coefficient between the first and second current blocking layers 18 and 19 and GaN.

FIG. 4 is a cross-sectional view of a nitride semiconductor laser device of the second comparative example in this disclosure, in which the third current blocking layer 22 is not provided. In FIG. 4, the same components as those of the nitride semiconductor laser device of the first illustrative embodiment shown in FIG. 3 are denoted by the same reference numerals, and the description of such components is omitted here.

As shown in FIG. 4, the third current blocking layer 22 is not formed unlike FIG. 3, and the p-type electrode 20 is formed covering the p-type contact layer 17, the first current blocking layer 18, and the second current blocking layer 19.

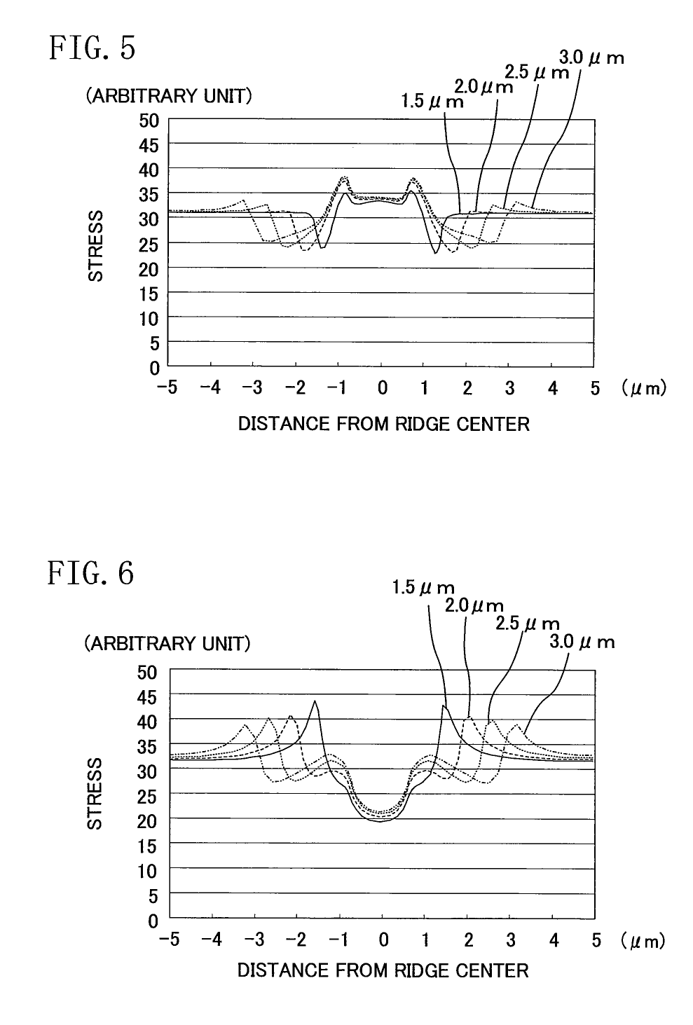

FIGS. 5 and 6 respectively show calculation results of compressive stress distributions observed when A1 is changed every 0.5 μm in the range from 0.8 μm to 2.3 μm for the nitride semiconductor laser device of the first illustrative embodiment and the nitride semiconductor laser device of the second comparative example shown in FIG. 4. FIGS. 5 and 6 show four cases of a distance from the center of the ridge portion to the second current blocking layer 19 of 1.5 μm, 2.0 μm, 2.5 μm, and 3.0 μm, where the width of the ridge portion is 1.4 μm. Note that FIGS. 5 and 6 show the calculation results of the stress in the direction parallel to the active layer, at the level of the p-type cladding layer 16 apart from the p-type electron block layer 15 by distance dp. In these graphs, compressive stress is regarded as positive.

As shown in FIG. 6, in the second comparative example, the compressive stress abruptly increases at each boundary between the second current blocking layer 19 and the space region between the second current blocking layer 19 and the ridge portion. The reason for this is considered that a large stress is generated at the boundary between the second current blocking layer 19 and the space region between the second current blocking layer 19 and the ridge portion due to the difference in heat expansion coefficient between the second current blocking layer 19 made of amorphous Si and the p-type cladding layer 16 made of GaN. Once the p-type cladding layer 16 is subjected to compressive stress, the refractive index of the stressed region increases. Therefore, the refractive index increases in the region of the p-type cladding layer 16 ranging from near each bottom edge of the ridge portion to the outside of the ridge portion. Moreover, it is found that the compressive stress increases as A1 shown in FIG. 4 is smaller. When the refractive index increases in the region of the p-type cladding layer 16 ranging from near each bottom edge of the ridge portion to the outside of the ridge portion, the effective refractive index difference (ΔN) between the inside and outside of the ridge portion decreases.

As a result of decrease in ΔN, the NFP in the horizontal fundamental transverse mode changes to spread in the horizontal direction, and α0 increases under the influence of the light absorption loss by the second current blocking layer 19 having light absorbency, thereby reducing the slope efficiency. Moreover, as the NFP spreads horizontally, the full width at half maximum of the horizontal spread angle of the FFP changes to decrease. If this decreases by about 2° compared with the case of having no change in refractive index, a desired FFP will no more be obtainable. Accordingly, in the second comparative example shown in FIG. 4, to obtain a desired FFP horizontal spread angle of 8° or more, the width of the ridge portion must be reduced, or ΔN must be set at a large value. However, as the width of the ridge portion is smaller, the series resistance of the device increases, increasing power consumption. As ΔN becomes larger, the horizontal high-order transverse mode becomes less easy to be cut off, and this causes degradation in kink level. In the second comparative example, therefore, it is difficult to obtain properties satisfying all of high slope efficiency, a large horizontal spread angle of 8° or more, and high kink level without causing increase in device series resistance.

In contrast to the above, in the nitride semiconductor laser device of the first illustrative embodiment, in which the third current blocking layer 22 is formed, it is found from FIG. 5 that the abrupt increase in stress generated near the boundary between the second current blocking layer 19 and the space region between the second current blocking layer 19 and the ridge portion is suppressed. In particular, the change in the refractive index of the portions of the p-type cladding layer 16 under the second current blocking layer 19 can be reduced. Therefore, in the nitride semiconductor laser device of the first illustrative embodiment, deformation of the NFP of spreading in the horizontal direction can be prevented, and hence the waveguide loss in the horizontal fundamental transverse mode by the second current blocking layer 19 can be reduced. Moreover, a desired FFP horizontal spread angle as wide as 8° or more can be obtained without reducing the width of the ridge portion, or increasing ΔN, more than necessary.

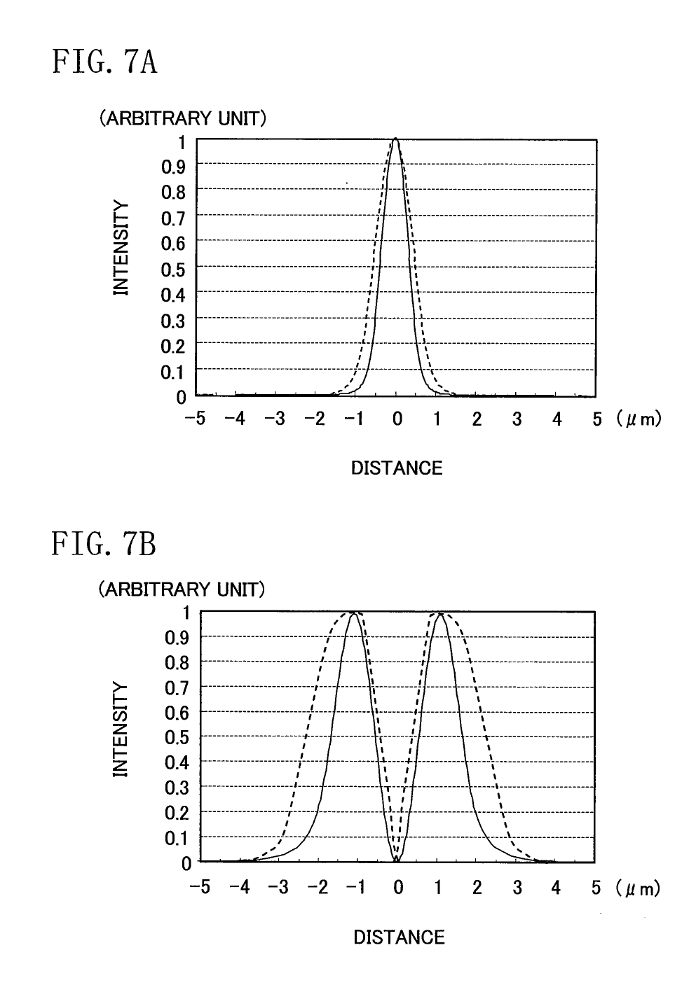

FIG. 7A shows calculation results of the NFP in the horizontal fundamental transverse mode observed when A1 is 0.8 μm in the first illustrative embodiment and the second comparative example. FIG. 7B shows calculation results of the NFP in the horizontal high-order transverse mode observed when A1 is 0.8 μm in the first illustrative embodiment and the second comparative example. In FIGS. 7A and 7B, the solid line and the broken line respectively represent the first illustrative embodiment and the second comparative example. The calculation was made assuming that the thicknesses of the first, second, and third current blocking layers 18, 19, and 22 are 0.05 μm, 0.08 μm, and 0.05 μm, respectively.

As shown in FIGS. 7A and 7B, with the formation of the third current blocking layer 22, the horizontal spread of the NFP can be reduced in both the horizontal fundamental transverse mode and the horizontal high-order transverse mode. In other words, with the structure of the nitride semiconductor laser device of the first illustrative embodiment, the waveguide loss in the horizontal fundamental transverse mode by the second current blocking layer 19 can be reduced, and a FFP having a wide horizontal spread angle can be achieved.

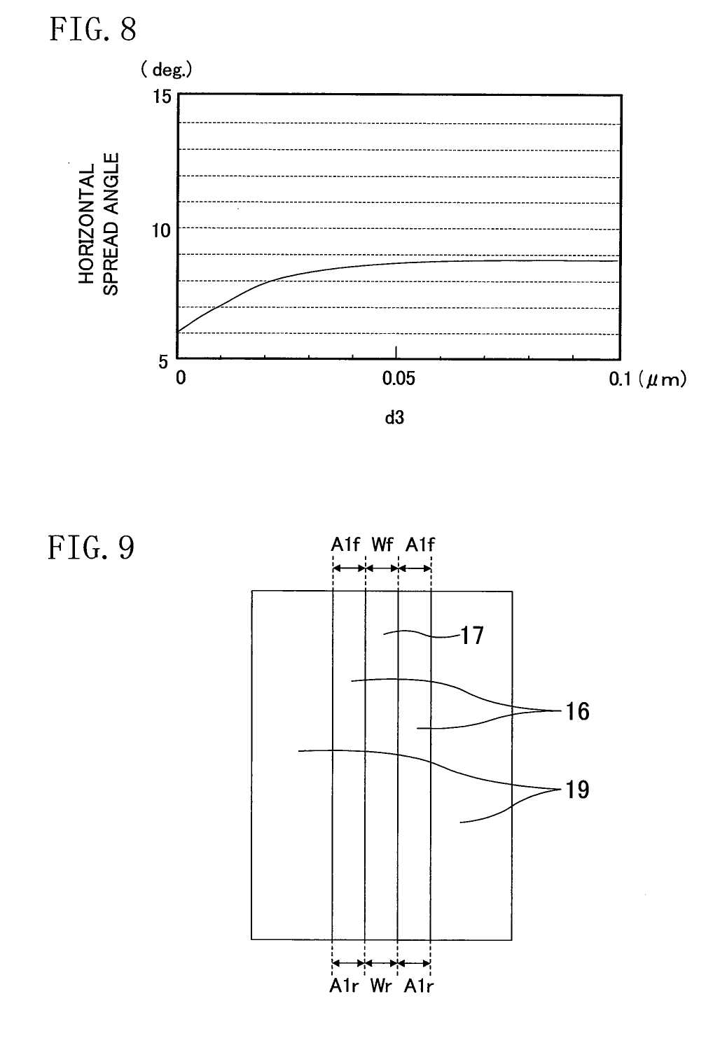

FIG. 8 shows calculation results of the FFP horizontal spread angle observed when the thickness d3 of the third current blocking layer 22 made of ZrO₂ is changed, considering a change in refractive index due to a stress caused by the difference in heat expansion coefficient between the first, second, and third current blocking layers 18, 19, and 22 and a member made of a nitride material forming the waveguide. Note that the structure used for this calculation is the same as the structure used for obtaining the calculation results shown in FIGS. 7A and 7B except that the thickness d3 of the third current blocking layer 22 is changed in FIG. 8.

As shown in FIG. 8, as the thickness d3 of the third current blocking layer 22 becomes larger, the FFP horizontal spread angle gradually increases. The reason for this is that with increase of the thickness d3 of the third current blocking layer 22, the compressive stress generated in a region of the p-type cladding layer 16 near each bottom edge of the ridge portion decreases due to the effect of compensating the difference in heat expansion coefficient by the third current blocking layer 22. This reduces the change in refractive index in this region and hence increases the FFP horizontal spread angle. From the calculation results shown in FIG. 8, it is found that the change of the FFP horizontal spread angle decreases when the thickness d3 of the third current blocking layer 22 is 0.03 μm or more, and the horizontal spread angle is roughly constant when the thickness d3 is 0.05 μm or more. In this embodiment, therefore, the thickness d3 of the third current blocking layer 22 is set at 0.05 μm.

FIG. 9 is a plan view of the nitride semiconductor laser device of the first illustrative embodiment. Note that in FIG. 9, the first current blocking layer 18, the p-type electrode 20, and the third current blocking layer 22 are omitted.

As shown in FIG. 9, the second current blocking layer 19 is formed so that the distance A1 between the second current blocking layer 19 and each bottom edge of the ridge portion on the front end facet side (A1f) of the device is the same as that on the rear end facet side (A1r). Also, the width (Wf) of the ridge portion on the front end facet side is the same as the width (Wr) thereof on the rear end facet side. The thickness (d2) of the second current blocking layer 19 may be set at 0.05 μm or more so that the waveguide loss is roughly constant. If it is excessively large, the stress caused by the difference in heat expansion coefficient between the second current blocking layer 19 and the waveguide made of a nitride material will increase. The thickness d2 should therefore be set at a value equal to or less than 0.1 μm. In this embodiment, d2 is set at 0.05 μm.

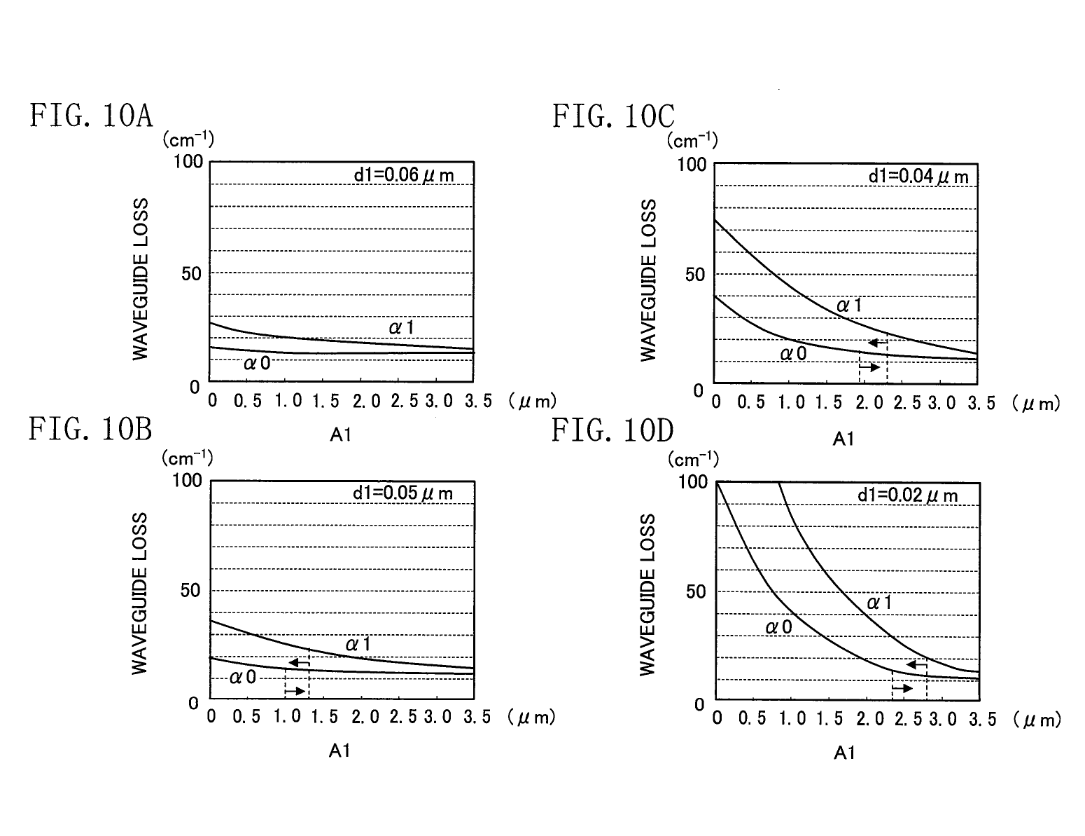

FIGS. 10A to 10D show calculation results of α0 and α1 with the thickness d1 of the first current blocking layer 18 and A1 as parameters in the structure described above. Specifically, FIGS. 10A, 10B, 10C, and 10D respectively show the results when d1 is 0.06 μm, 0.05 μm, 0.04 μm, and 0.02 μm.

As described earlier, α0 must be 15 cm⁻¹ or less to obtain high slope efficiency, and Δα must be 10 cm⁻¹ or more to prevent occurrence of a kink. When A1 is large, the light distribution is free from the influence of light absorption by the second current blocking layer 19. Therefore, the waveguide losses α0 and α1 are both small, and hence the effect of formation of the second current blocking layer 19 is lost. When A1 is small, α0 increases, reducing the slope efficiency. Accordingly, the value of A1 must be set to satisfy the requirements that α0 is 15 cm⁻¹ or less and Δα is 10 cm⁻¹ or more.

As shown in FIG. 10A, when d1 is 0.06 μm, in which the amount of light entering the second current blocking layer 19 is small, it is only when A1 is around 0.5 μm that the requirements that α0 is 15 cm⁻¹ or less and Δα is 10 cm⁻¹ or more are satisfied.

As shown in FIG. 10B, when d1 is 0.05 μm, it is when A1 is in the range of 1.0 μm to 1.3 μm that the requirements that α0 is 15 cm⁻¹ or less and Δα is 10 cm⁻¹ or more are satisfied.

As shown in FIG. 10C, when d1 is 0.04 μm, it is when A1 is in the range of 1.9 μm to 2.3 μm that the requirements that α0 is 15 cm⁻¹ or less and Δα is 10 cm⁻¹ or more are satisfied.

As shown in FIG. 10D, when d1 is 0.02 μm, it is when A1 is in the range of 2.3 μm to 2.8 μm that the requirements that α0 is 15 cm⁻¹ or less and Δα is 10 cm⁻¹ or more are satisfied.

In the first illustrative embodiment, by setting A1 at any of the above ranges, high slope efficiency, high kink level due to suppression of oscillation in the horizontal high-order transverse mode, and a wide FFP horizontal spread angle of 8° or more can be achieved. In this embodiment, α0 of 15 cm⁻¹ and Δα of 11 cm⁻¹ are obtained by setting d1 at 0.05 μm and A1 at 1 μm.

In the first illustrative embodiment, SiO₂ was used for the first current blocking layer 18, amorphous Si for the second current blocking layer 19, and ZrO₂ for the third current blocking layer 22. The materials are not limited to these dielectric materials, but silicon nitride (SiN), titanium dioxide (TiO₂), tantalum dioxide (TaO₂), aluminum oxide (Al₂O₃), and the like may be used. The current blocking layers are just required to satisfy ηg>η1, ηg>η2, and ηg<η3 where η1, η2, and η3 are respectively the heat expansion coefficients of the first, second, and third current blocking layers 18, 19, and 22, and ηg is the heat expansion coefficient of gallium nitride, and the second current blocking layer 19 is required to have absorbency for laser light. The first current blocking layer 18 may not be formed on the top portion of each side face of the p-type cladding layer 16. This structure will reduce the thickness of the first current blocking layer formed on each side face of the ridge portion in the direction normal to the substrate, and hence permit further reduction of the stress on the cladding layer at each bottom edge of the ridge portion generated by the difference in heat expansion coefficient between the first current blocking layer and the nitride material constituting the waveguide.

### First Variation of First Illustrative Embodiment

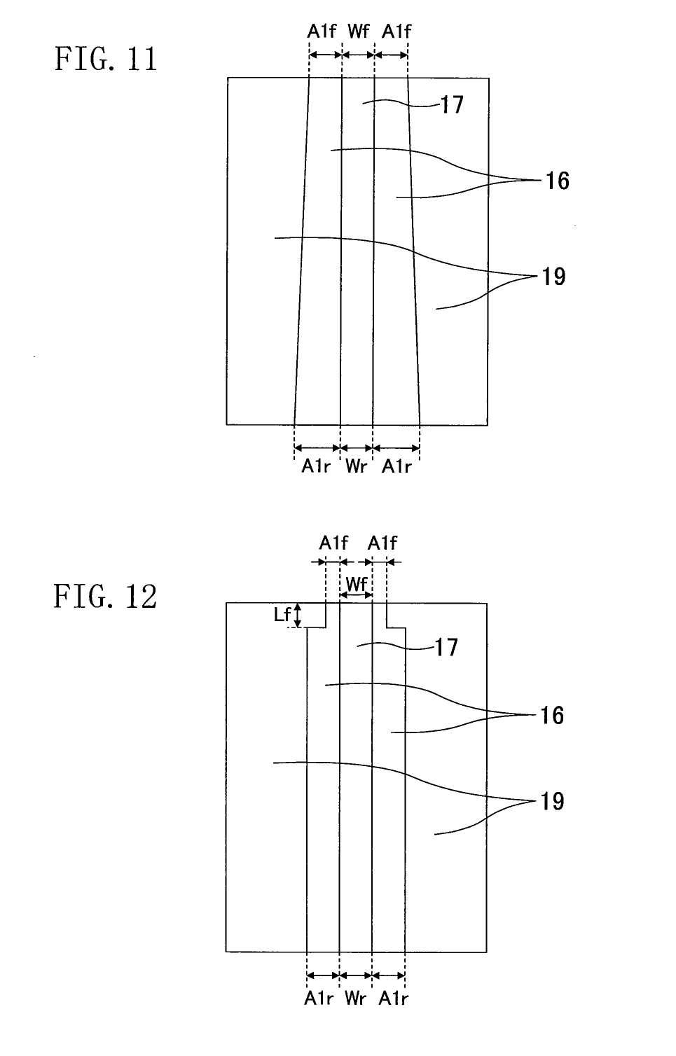

FIG. 11 is a plan view of a nitride semiconductor laser device of a first variation of the first illustrative embodiment. Note that the first current blocking layer 18, the p-type electrode 20, and the third current blocking layer 22 are omitted in FIG. 11. In this variation, description is omitted for portions having the same structure as in the first illustrative embodiment.

As shown in FIG. 11, in the first variation of the first illustrative embodiment, the distance from the second current blocking layer 19 to the ridge portion is gradually reduced with a constant gradient from the rear end facet side toward the front end facet side, thereby to make the distance A1f of the second current blocking layer 19 from each bottom edge of the ridge portion on the front end facet side smaller than the distance A1r thereof from each bottom edge of the ridge portion on the rear end facet side. Also, the reflectance Rf on the front end facet side and the reflectance Rr on the rear end facet side are set to satisfy Rf<Rr. The width of the ridge portion is fixed: the width (Wf) of the ridge portion on the front end facet side is the same as the width (Wr) thereof on the rear end facet side.

In a nitride semiconductor laser device, the band gap energy of the p-type cladding layer 16 constituting the waveguide and the semiconductor layer constituting the semiconductor substrate 11 is larger than that of the active layer made of InGaN. Therefore, laser light scattered from the waveguide due to microscopic asperities on the side faces of the ridge portion is hardly absorbed by semiconductor layers other than the active layer, but is reflected by the waveguide and the electrodes to be output from the front end facet. Under the influence of such scattered light, the shape of the FFP may be disturbed and a desired unimodial FFP pattern may not be obtained. To prevent this, scattered light as a cause of FFP disturbance should just be absorbed by the second current blocking layer 19 at the front end facet that is the laser light output side and removed. In this way, a unimodial FFP can be obtained.

In this variation, by setting A1f at a value in the range of 0.5 μm to 2 μm, scattered light components from the waveguide, as a cause of FFP disturbance, can be removed by the second current blocking layer 19 near the front end facet.

In the first variation of the first illustrative embodiment, by reducing the distance between the ridge portion and the second current blocking layer 19 on the front end facet side where the light density is high, the waveguide loss in the horizontal high-order transverse mode can be increased, and furthermore scattered light from the waveguide can be absorbed by the second current blocking layer 19 at the front end facet. As a result, a good unimodial FFP can be obtained. Also, high slope efficiency can be obtained in the current-light output characteristics, and hence occurrence of a kink can be suppressed.

### Second Variation of First Illustrative Embodiment

FIG. 12 is a plan view of a nitride semiconductor laser device of a second variation of the first illustrative embodiment. Note that the first current blocking layer 18, the p-type electrode 20, and the third current blocking layer 22 are omitted in FIG. 12. In this variation, description is omitted for portions having the same structure as in the first illustrative embodiment.

As shown in FIG. 12, in the second variation of the first illustrative embodiment, A1f is made smaller than A1r only in a region covering distance Lf from the front end facet in the cavity length direction. Note that Rf is smaller than Rr. The width of the ridge portion is fixed: Wf and Wr are the same.

In this variation, by setting A1f at a value in the range of 0.5 μm to 2 μm, scattered light components from the waveguide, as a cause of FFP disturbance, can be removed by the second current blocking layer 19 near the front end facet. As Lf is larger, the effect of removing scattered light increases. However, if it is excessively large, the waveguide loss in the horizontal fundamental transverse mode will increase. Hence, Lf may be set at a value in the range of 5 μm to 50 μm to be 10% or less of the cavity length, to prevent redundant increase in waveguide loss in the horizontal fundamental transverse mode, whereby decrease in slope efficiency can be suppressed.

In the second variation of the first illustrative embodiment, by reducing the distance between each side face of the ridge waveguide and the light absorption film on the front end facet side where the light density is high, the waveguide loss in the horizontal high-order transverse mode can be increased, and furthermore scattered light from the waveguide can be absorbed by the second current blocking layer 19 at the front end facet. As a result, a good unimodial FFP can be obtained. Also, high slope efficiency can be obtained in the current-light output characteristics, and hence occurrence of a kink can be suppressed.

### Third Variation of First Illustrative Embodiment

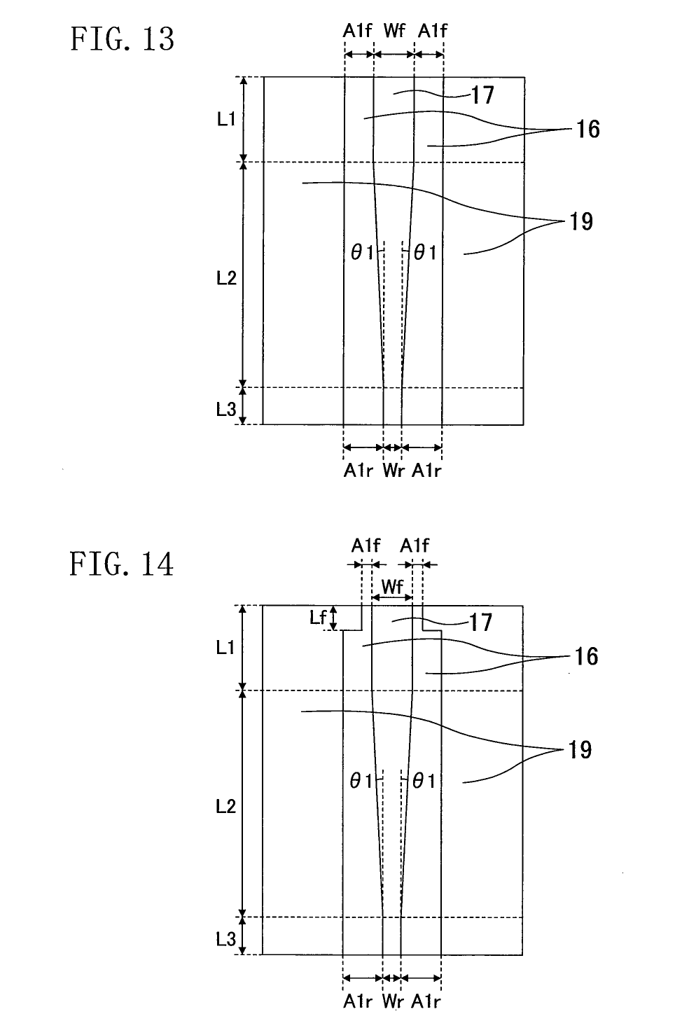

FIG. 13 is a plan view of a nitride semiconductor laser device of a third variation of the first illustrative embodiment. Note that the first current blocking layer 18, the p-type electrode 20, and the third current blocking layer 22 are omitted in FIG. 13. In this variation, description is omitted for portions having the same structure as in the first illustrative embodiment.

As shown in FIG. 13, in the third variation of the first illustrative embodiment, the ridge portion has a region where the width changes along the cavity length, to give a structure that Wf is larger than Wr. The width of the ridge portion is fixed in a region covering distance L1 from the front end facet and a region covering distance L3 from the rear end facet, but changes at a fixed angle θ1 in a region covering distance L2 between the above two regions. In the region of L2, the distance from the second current blocking layer 19 to the ridge portion changes with the change in ridge width, in which A1f is smaller than A1r. Note that Rf is smaller than Rr.

In this variation, by setting A1f at a value in the range of 0.5 μm to 2 μm, scattered light components from the waveguide, as a cause of FFP disturbance, can be removed by the second current blocking layer 19 near the front end facet.

In this variation, since Wf is larger than Wr, a larger amount of current can be injected on the front end facet side where the light density is high. Hence, the efficiency of converting the current to light improves. Also, by setting A1r to be larger than A1f, it is possible to increase the difference in waveguide loss between the horizontal fundamental transverse mode and the horizontal high-order transverse mode while reducing the light absorption loss in the horizontal fundamental transverse mode by the second current blocking layer 19. In addition, by reducing A1f, scattered light from the waveguide can be absorbed by the second current blocking layer 19 on the front end facet side where the light density is high.

In such a stripe-shaped laser device, guided light tends to scatter when the ridge width changes along the cavity length. To remove scattered light, it is advisable to set A1f at a value less than 0.5 μm. However, if A1f is excessively reduced, the waveguide loss in the horizontal fundamental transverse mode will increase. In consideration of this, the angle θ1 at which the ridge width changes may be set to be as small as 2° or less. With this setting, radiation scattering of laser light from the side faces of the ridge portion and disturbance of the FFP shape can be suppressed. In this variation, θ1 is set at 0.3°, to suppress scattering of light from the side faces of the ridge portion.

In the third variation of the first illustrative embodiment, a good unimodial FFP can be obtained. Also, high slope efficiency can be obtained in the current-light output characteristics, and hence occurrence of a kink can be suppressed.

### Fourth Variation of First Illustrative Embodiment

FIG. 14 is a plan view of a nitride semiconductor laser device of a fourth variation of the first illustrative embodiment. Note that the first current blocking layer 18, the p-type electrode 20, and the third current blocking layer 22 are omitted in FIG. 14. In this variation, description is omitted for portions having the same structure as in the first illustrative embodiment.

As shown in FIG. 14, in the fourth variation of the first illustrative embodiment, the ridge portion has a region where the width changes along the cavity length, to give a structure that Wf is larger than Wr. The width of the ridge portion is fixed in a region covering distance L1 from the front end facet and a region covering distance L3 from the rear end facet, but changes at a fixed angle θ1 in a region covering distance L2 between the above two regions. Moreover, in a region covering distance Lf from the front end facet in the cavity length direction, the distance from the second current blocking layer 19 to the ridge portion is reduced. As a result, A1f is smaller than A1r. Note that Rf is smaller than Rr.

In this variation, by setting A1f at a value in the range of 0.5 μm to 2 μm, scattered light components from the waveguide, as a cause of FFP disturbance, can be removed by the second current blocking layer 19 near the front end facet. As Lf is larger, the effect of removing scattered light increases. However, if it is excessively large, the waveguide loss in the horizontal fundamental transverse mode will increase. Hence, Lf may be set at a value in the range of 5 μm to 50 μm to be 10% or less of the cavity length, to prevent redundant increase in waveguide loss in the horizontal fundamental transverse mode, whereby decrease in slope efficiency can be suppressed.

In this variation, since Wf is larger than Wr, a larger amount of current can be injected on the front end facet side where the light density is high. Hence, the efficiency of converting the current to light improves. A smaller ridge width will increase spread of the light distribution to the outside of the ridge portion. Therefore, by setting A1r to be larger than A1f, it is possible to increase the difference in waveguide loss between the horizontal fundamental transverse mode and the horizontal high-order transverse mode while reducing the light absorption loss in the horizontal fundamental transverse mode by the second current blocking layer 19. In addition, by reducing A1f, scattered light from the waveguide can be absorbed by the second current blocking layer 19 on the front end facet side where the light density is high.

In such a stripe-shaped laser device, guided light tends to scatter when the ridge width changes along the cavity length. To remove scattered light, it is advisable to set A1f at a value less than 0.5 μm. However, if A1f is excessively reduced, the waveguide loss in the horizontal fundamental transverse mode will increase. In consideration of this, the angle θ1 at which the ridge width changes may be set to be as small as 2° or less. With this setting, radiation scattering of laser light from the side faces of the ridge portion and disturbance of the FFP shape can be suppressed. In this variation, θ1 is set at 0.3°, to suppress scattering of light from the side faces of the ridge portion.

In the fourth variation of the first illustrative embodiment, a good unimodial FFP can be obtained. Also, high slope efficiency can be obtained in the current-light output characteristics, and hence occurrence of a kink can be suppressed.

### Fifth Variation of First Illustrative Embodiment

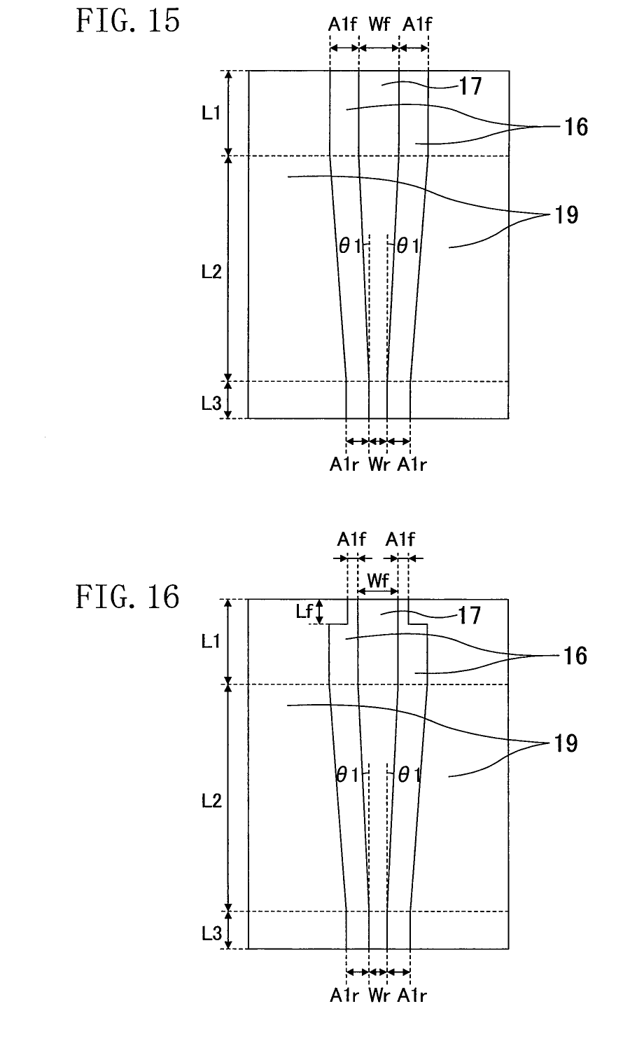

FIG. 15 is a plan view of a nitride semiconductor laser device of a fifth variation of the first illustrative embodiment. Note that the first current blocking layer 18, the p-type electrode 20, and the third current blocking layer 22 are omitted in FIG. 15. In this variation, description is omitted for portions having the same structure as in the first illustrative embodiment.

As shown in FIG. 15, in the fifth variation of the first illustrative embodiment, the ridge portion has a region where the width changes along the cavity length, to give a structure that Wf is larger than Wr. The width of the ridge portion is fixed in a region covering distance L1 from the front end facet and a region covering distance L3 from the rear end facet, but changes at a fixed angle θ1 in a region covering distance L2 between the above two regions. In this variation, the distance from the second current blocking layer 19 to the ridge portion is kept fixed. That is, A1f and A1r are the same. Note that Rf is smaller than Rr.

In this variation, by setting A1f at a value in the range of 0.5 μm to 2 μm, scattered light components from the waveguide, as a cause of FFP disturbance, can be removed by the second current blocking layer 19 near the front end facet.

In this variation, since Wf is larger than Wr, a larger amount of current can be injected on the front end facet side where the light density is high. Hence, the efficiency of converting the current to light improves.

In such a stripe-shaped laser device, guided light tends to scatter when the ridge width changes along the cavity length. In consideration of this, A1r and A1f are set to be the same. With this setting, scattered light generated near the region covering the distance L1 from the front end facet and the region covering the distance L3 from the rear end facet can be absorbed by the second current blocking layer 19 and removed. To remove scattered light, it is advisable to set A1f at a value less than 0.5 μm. However, if A1f is excessively reduced, the waveguide loss in the horizontal fundamental transverse mode will increase. In consideration of this, the angle θ1 at which the width of the ridge portion changes may be set to be as small as 2° or less. With this setting, radiation scattering of laser light from the side faces of the ridge portion and disturbance of the FFP shape can be suppressed. In this variation, θ1 is set at 0.3°, to suppress scattering of light from the side faces of the ridge portion.

In the fifth variation of the first illustrative embodiment, a good unimodial FFP can be obtained. Also, high slope efficiency can be obtained in the current-light output characteristics, and hence occurrence of a kink can be suppressed.

### Sixth Variation of First Illustrative Embodiment

FIG. 16 is a plan view of a nitride semiconductor laser device of a sixth variation of the first illustrative embodiment. Note that the first current blocking layer 18, the p-type electrode 20, and the third current blocking layer 22 are omitted in FIG. 16. In this variation, description is omitted for portions having the same structure as in the first illustrative embodiment.

As shown in FIG. 16, in the sixth variation of the first illustrative embodiment, the ridge portion has a region where the width changes along the cavity length, to give a structure that Wf is larger than Wr. The width of the ridge portion is fixed in a region covering distance L1 from the front end facet and a region covering distance L3 from the rear end facet, but changes at a fixed angle θ1 in a region covering distance L2 between the above two regions. In this variation, the distance from the second current blocking layer 19 to the ridge portion is kept fixed except for a region covering distance Lf from the front end facet in the cavity length direction. In the region covering the distance Lf from the front end facet in the cavity length direction, the distance from the second current blocking layer 19 to the ridge portion is reduced. As a result, the distance A1f from the second current blocking layer 19 to the ridge portion on the front end facet side is smaller than the distance A1r from the second current blocking layer 19 to the ridge portion on the rear end facet side. Note that Rf is smaller than Rr.

In this variation, by setting A1f at a value in the range of 0.5 μm to 2 μm, scattered light components from the waveguide, as a cause of FFP disturbance, can be removed by the second current blocking layer 19 near the front end facet.

In this variation, since Wf is larger than Wr, a larger amount of current can be injected on the front end facet side where the light density is high. Hence, the efficiency of converting the current to light improves.

In this variation, as Lf is larger, the effect of removing scattered light increases. However, if it is excessively large, the waveguide loss in the horizontal fundamental transverse mode will increase. Hence, Lf may be set at a value in the range of 5 μm to 50 μm to be 10% or less of the cavity length, to prevent redundant increase in waveguide loss in the horizontal fundamental transverse mode, whereby decrease in slope efficiency can be suppressed.

In such a stripe-shaped laser device, guided light tends to scatter when the ridge width changes along the cavity length. In consideration of this, the distance from the second current blocking layer 19 to the ridge portion is kept fixed except for the region Lf. With this setting, scattered light occurring near the region covering the distance L1 from the front end facet and the region covering the distance L3 from the rear end facet can be absorbed by the second current blocking layer 19 and removed. To remove scattered light, it is advisable to set A1f at a value less than 0.5 μm. However, if A1f is excessively reduced, the waveguide loss in the horizontal fundamental transverse mode will increase. In consideration of this, the angle θ1 at which the width of the ridge portion changes may be set to be as small as 2° or less. With this setting, radiation scattering of laser light from the side faces of the ridge portion and disturbance of the FFP shape can be suppressed. In this variation, θ1 is set at 0.3°, to suppress scattering of light from the side faces of the ridge portion.

In the sixth variation of the first illustrative embodiment, a good unimodial FFP can be obtained. Also, high slope efficiency can be obtained in the current-light output characteristics, and hence occurrence of a kink can be suppressed.

### Seventh Variation of First Illustrative Embodiment

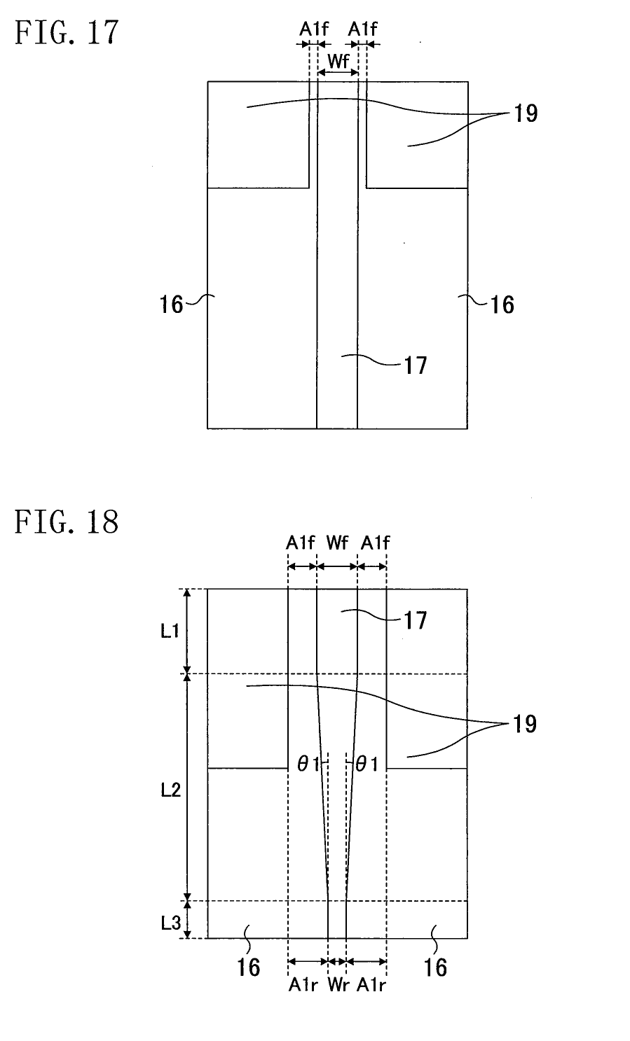

FIG. 17 is a plan view of a nitride semiconductor laser device of a seventh variation of the first illustrative embodiment. Note that the first current blocking layer 18, the p-type electrode 20, and the third current blocking layer 22 are omitted in FIG. 17. In this variation, description is omitted for portions having the same structure as in the first illustrative embodiment.

As shown in FIG. 17, in the seventh variation of the first illustrative embodiment, the second current blocking layer 19 is formed only on the front end facet side. The distance from the second current blocking layer 19 to the ridge portion is fixed at A1f, and the width of the ridge portion is fixed at Wf. Note that Rf is smaller than Rr.

In this variation, by setting A1f at a value in the range of 0.5 μm to 2 μm, scattered light components from the waveguide, as a cause of FFP disturbance, can be removed by the second current blocking layer 19 near the front end facet. Also, since the second current blocking layer 19 is formed only in a region on the front end facet side where the light density is high, only the waveguide loss in the horizontal high-order transverse mode can be increased without increasing the waveguide loss in the horizontal fundamental transverse mode more than necessary.

In this variation, A1f may be further reduced in a region covering distance Lf from the front end facet in the cavity length direction. In this case, the effect of removing scattered light can be further increased. As Lf is larger, the effect of removing scattered light increases. However, if it is excessively large, the waveguide loss in the horizontal fundamental transverse mode will increase. Hence, Lf may be set at a value in the range of 5 μm to 50 μm to be 10% or less of the cavity length, to prevent redundant increase in waveguide loss in the horizontal fundamental transverse mode, whereby decrease in slope efficiency can be suppressed.

In the seventh variation of the first illustrative embodiment, a good unimodial FFP can be obtained. Also, high slope efficiency can be obtained in the current-light output characteristics, and hence occurrence of a kink can be suppressed.

### Eighth Variation of First Illustrative Embodiment

FIG. 18 is a plan view of a nitride semiconductor laser device of an eighth variation of the first illustrative embodiment. Note that the first current blocking layer 18, the p-type electrode 20, and the third current blocking layer 22 are omitted in FIG. 18. In this variation, description is omitted for portions having the same structure as in the first illustrative embodiment.

As shown in FIG. 18, in the eighth variation of the first illustrative embodiment, the second current blocking layer 19 is formed only on the front end facet side. Also, the ridge portion has a region where the width changes along the cavity length, to give a structure that Wf is larger than Wr. The width of the ridge portion is fixed in a region covering distance L1 from the front end facet and a region covering distance L3 from the rear end facet, but changes at a fixed angle θ1 in a region covering distance L2 between the above two regions. In the region of L2, the distance from the second current blocking layer 19 to the ridge portion also changes with the change in ridge width, in which A1f is smaller than A1r. Note that Rf is smaller than Rr.

In this variation, by setting A1f at a value in the range of 0.5 μm to 2 μm, scattered light components from the waveguide, as a cause of FFP disturbance, can be removed by the second current blocking layer 19 near the front end facet. By setting A1f in the region near the front end facet to be smaller than A1r, the effect of removing scattered light can be increased. Also, since the second current blocking layer 19 is formed only in the region on the front end facet side where the light density is high, only the waveguide loss in the horizontal high-order transverse mode can be increased without increasing the waveguide loss in the horizontal fundamental transverse mode more than necessary.

In this variation, A1f may be further reduced in a region covering distance Lf from the front end facet in the cavity length direction. In this case, the effect of removing scattered light can be further increased. As Lf is larger, the effect of removing scattered light increases. However, if it is excessively large, the waveguide loss in the horizontal fundamental transverse mode will increase. Hence, Lf may be set at a value in the range of 5 μm to 50 μm to be 10% or less of the cavity length, to prevent redundant increase in waveguide loss in the horizontal fundamental transverse mode, whereby decrease in the slope efficiency can be suppressed.

In such a stripe-shaped laser device, guided light tends to scatter when the ridge width changes along the cavity length. To remove scattered light, it is advisable to set A1f at a value less than 0.5 μm. However, if A1f is excessively reduced, the waveguide loss in the horizontal fundamental transverse mode will increase. In consideration of this, the angle θ1 at which the ridge width changes may be set to be as small as 2° or less. With this setting, radiation scattering of laser light from the side faces of the ridge portion and disturbance of the FFP shape can be suppressed. In this variation, θ1 is set at 0.3°, to suppress scattering of light from the side faces of the ridge portion.

In the eighth variation of the first illustrative embodiment, a good unimodial FFP can be obtained. Also, high slope efficiency can be obtained in the current-light output characteristics, and hence occurrence of a kink can be suppressed.

### Ninth Variation of First Illustrative Embodiment

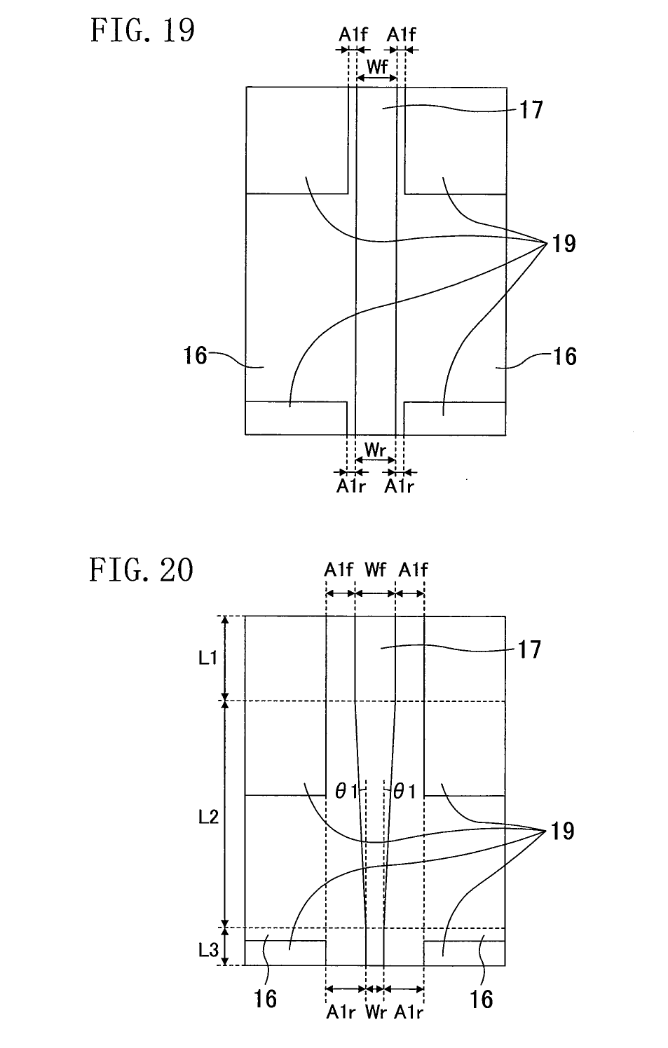

FIG. 19 is a plan view of a nitride semiconductor laser device of a ninth variation of the first illustrative embodiment. Note that the first current blocking layer 18, the p-type electrode 20, and the third current blocking layer 22 are omitted in FIG. 19. In this variation, description is omitted for portions having the same structure as in the first illustrative embodiment.

As shown in FIG. 19, in the ninth variation of the first illustrative embodiment, the second current blocking layer 19 is formed only in regions near the front end facet and the rear end facet. Since the distance from the second current blocking layer 19 to the ridge portion is fixed, A1f and A1r are the same. Also, since the width of the ridge portion is fixed, Wf and Wr are the same. Note that Rf is smaller than Rr.

In the ninth variation of the first illustrative embodiment, the following effect is obtained in addition to the effect described in the seventh variation. Scattered light reflected from the rear end facet to be returned to the inside of the cavity can be absorbed by the second current blocking layer 19 near the rear end facet and removed. Therefore, generation of noise in laser light intensity, which may occur when scattered light from the waveguide is reflected from the rear end facet and absorbed into the active layer, can be prevented. Also, since the second current blocking layer 19 is formed only in the region near the rear end facet in addition to the region near the front end facet, decrease in slope efficiency can be suppressed.

### Tenth Variation of First Illustrative Embodiment

FIG. 20 is a plan view of a nitride semiconductor laser device of a tenth variation of the first illustrative embodiment. Note that the first current blocking layer 18, the p-type electrode 20, and the third current blocking layer 22 are omitted in FIG. 20. In this variation, description is omitted for portions having the same structure as in the first illustrative embodiment.

As shown in FIG. 20, in the tenth variation of the first illustrative embodiment, the second current blocking layer 19 is formed only in regions near the front end facet and the rear end facet. The ridge portion has a region where the width changes along the cavity length, to give a structure that Wf is larger than Wr. The width of the ridge portion is fixed in a region covering distance L1 from the front end facet and a region covering distance L3 from the rear end facet, but changes at a fixed angle θ1 in a region covering distance L2 between the above two regions. In the region of L2, the distance from the second current blocking layer 19 to the ridge portion also changes with the change in ridge width, in which A1f is smaller than A1r. Note that Rf is smaller than Rr.

In the tenth variation of the first illustrative embodiment, the following effect is obtained in addition to the effect described in the eighth variation. Scattered light reflected from the rear end facet to be returned to the inside of the cavity can be absorbed by the second current blocking layer 19 near the rear end facet and removed. Therefore, generation of noise in laser light intensity, which may occur when scattered light from the waveguide is reflected from the rear end facet and absorbed into the active layer, can be prevented. Also, since the second current blocking layer 19 is formed only in the region near the rear end facet in addition to the region near the front end facet, decrease in slope efficiency can be suppressed.

### Second Illustrative Embodiment

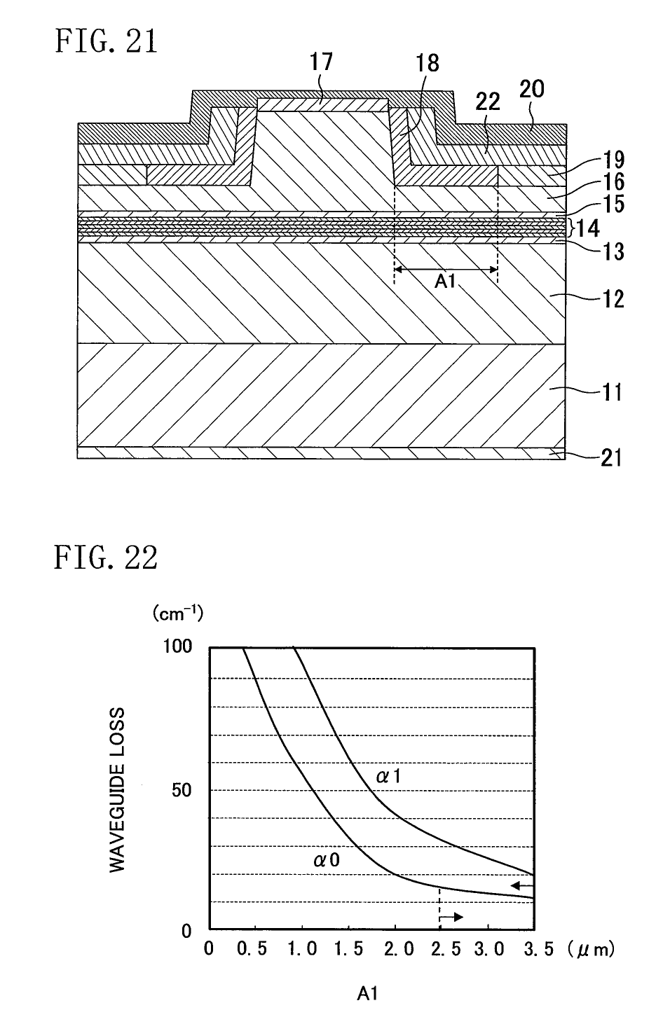

FIG. 21 is a cross-sectional view of a nitride semiconductor laser device of the second illustrative embodiment. In FIG. 21, the structure covering the semiconductor substrate 11 through the p-type contact layer 17 and the structure of the n-type electrode 21 are the same as those in the first illustrative embodiment. These components are therefore denoted by the same reference numerals, and description thereof is omitted here.

As shown in FIG. 21, the first current blocking layer 18 is formed on the side faces of the ridge portion of the p-type cladding layer 16 and on regions of the flat portions thereof covering distance A1 from the ridge portion. The second current blocking layer 19 is formed on regions of the flat portions of the p-type cladding layer 16 to abut against the first current blocking layer 18 at the positions of the distance A1 from the ridge portion. The third current blocking layer 22 is formed on the first current blocking layer 18 and the second current blocking layer 19. The p-type electrode 20 is formed to cover the p-type contact layer 17, the first current blocking layer 18, and the third current blocking layer 22.

FIG. 22 shows calculation results of α0 and α1 obtained when A1 shown in FIG. 21 is changed. Note that, like the plan view of the first illustrative embodiment shown in FIG. 9, the widths of the ridge portion on the front end facet side and the rear end facet side are the same, and the distances from the ridge portion to the second current blocking layer 19 on the front end facet side and the back end facet side are the same. Note also that, the thicknesses of the first current blocking layer 18, the second current blocking layer 19, and the third current blocking layer 22 are all set at 0.05 μm for the reason described in the first illustrative embodiment.

In the second illustrative embodiment, in which the second current blocking layer 19 is formed right on the p-type cladding layer 16, both α0 and α1 are large when A1 is small as shown in FIG. 22. Therefore, in comparison with the graphs shown in FIGS. 10A to 10D for the first illustrative embodiment in terms of the same A1, it is found that Δα can be made larger in the second illustrative embodiment. In particular, it is found that, to obtain α0 of 15 cm⁻¹ or less and Δα of 10 cm⁻¹ or more, A1 may be set at a value in the range of 2.5 μm to 3.5 μm. In this embodiment, A1 is set at 2.5 μm, to obtain α0 of 15 cm⁻¹ and Δα of 18 cm⁻¹.

In the nitride semiconductor laser device of the second illustrative embodiment, Δα can be increased, and hence the kink level can be further improved.

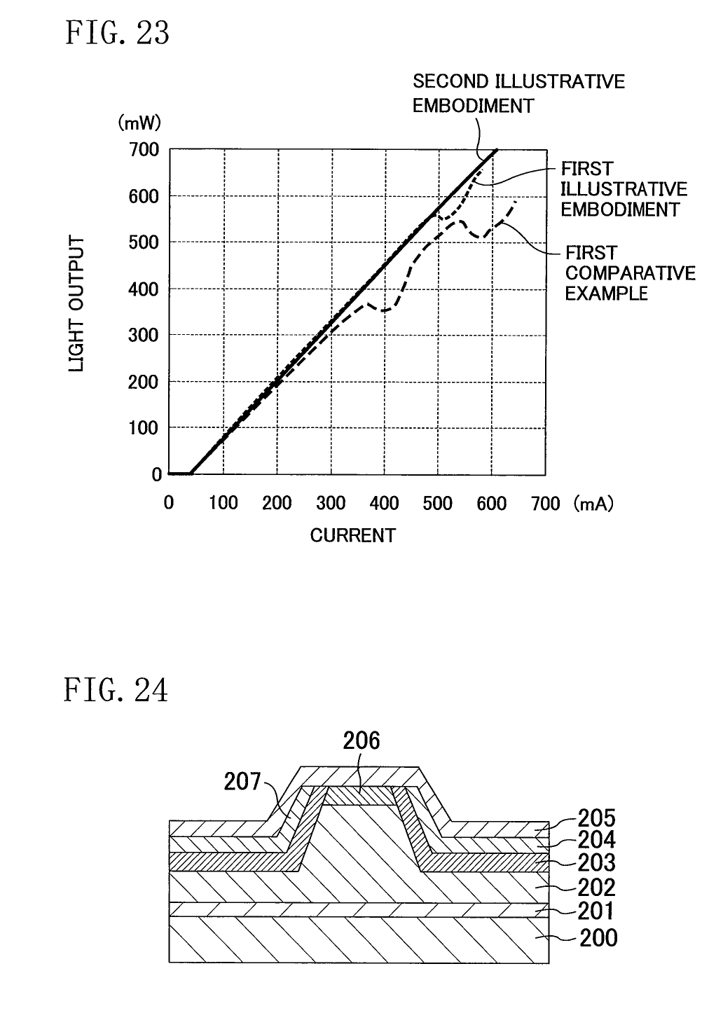

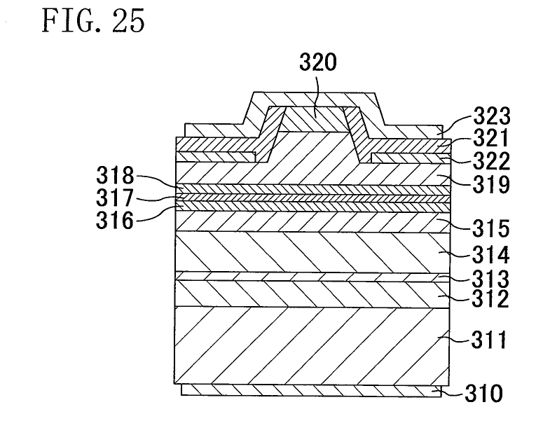

FIG. 23 shows the current-light output characteristics of the nitride semiconductor laser devices of the first and second illustrative embodiments and the nitride semiconductor laser device of the first comparative example shown in FIG. 1. Assume that in the nitride semiconductor laser device of the first comparative example, d1 is set at 0.081 μm and d2 at 0.05 μm, to obtain α0 of 15 cm⁻¹ and Δα of 4 cm⁻¹.

As shown in FIG. 23, in the range of light output of 100 mW or less, all of the nitride semiconductor laser devices of the first illustrative embodiment, the second illustrative embodiment, and the first comparative example exhibit roughly the same emission efficiency. When the light output is high, the nitride semiconductor laser device of the first illustrative embodiment is higher in kink level than the nitride semiconductor laser device of the first comparative example by about 200 mW. In the nitride semiconductor laser device of the second illustrative embodiment, no kink occurs even in high-output operation of 700 mW. The reason for the above results is as follows. While only a Δα value as small as 4 cm⁻¹ is obtained in the nitride semiconductor laser device of the first comparative example to avoid the waveguide loss in the horizontal fundamental transverse mode from exceeding 15 cm⁻¹, the Δα value can be increased to 12 cm⁻¹ in the first illustrative embodiment and 18 cm⁻¹ in the second illustrative embodiment. In this way, by reducing α0 and increasing Δα, it is possible to obtain a high kink level while keeping high slope efficiency.

The nitride semiconductor laser device of the first comparative example does not have the third current blocking layer 22 that can compensate the difference in heat expansion coefficient between the first and second current blocking layers 18 and 19 and the nitride material. Therefore, to obtain a FFP horizontal spread angle of 9.5°, it is necessary to reduce the width of the ridge portion from 1.4 μm to 1 μm, or increase ΔN by about 1.5 times from 5×10⁻³ to 8×10⁻³, the value obtained when no consideration is given to a change in refractive index due to a stress caused by the difference in heat expansion coefficient. Hence, in the first comparative example, when the device is subjected to high-output operation, the series resistance increases with the decrease in ridge width, increasing power consumption. As a result, the emission efficiency decreases due to self-heating of the device. Otherwise, with the increase in ΔN, the horizontal high-order transverse mode becomes less easy to be cut off, and this lowers the kink level. In contrast to the above, both the nitride semiconductor laser devices of the first illustrative embodiment and the second illustrative embodiment can obtain a FFP full width at half maximum of 9.5° in the horizontal direction and 19° in the vertical direction (not shown).

In the second illustrative embodiment, SiO₂ was used for the first current blocking layer 18, amorphous Si for the second current blocking layer 19, and ZrO₂ for the third current blocking layer 22. The materials are not limited to these dielectric materials, but silicon nitride (SiN), titanium dioxide (TiO₂), tantalum dioxide (TaO₂), aluminum oxide (Al₂O₃), and the like may be used. The current blocking layers are just required to satisfy ηg>η1, ηg>η2, and ηg<η3 where η1, η2, and η3 are respectively the heat expansion coefficients of the first, second, and third current blocking layers 18, 19, and 22, and ηg is the heat expansion coefficient of gallium nitride, and the second current blocking layer 19 is required to have absorbency for laser light. The first current blocking layer 18 may not be formed on the top portion of each side face of the p-type cladding layer 16. This structure will reduce the thickness of the first current blocking layer formed on each side face of the ridge portion in the direction normal to the substrate, and hence permit further reduction of the stress exerted on the cladding layer at each bottom edge of the ridge portion caused by the difference in heat expansion coefficient between the first current blocking layer and the nitride material constituting the waveguide.

The variations of the first illustrative embodiment described above can also be applied to the second illustrative embodiment.

As described above, in the nitride semiconductor laser device of the present disclosure, the oscillation threshold current value can be reduced, the slope efficiency can be improved, and the kink level in the current-light output characteristics can be improved, obtaining a FFP having no disturbance. Hence, the present disclosure is particularly useful in nitride semiconductor laser devices having a ridge structure.

What is claimed is:

1. A nitride semiconductor laser device, comprising:
an active layer made of a nitride formed on a semiconductor substrate;
a stripe-shaped ridge waveguide including a cladding layer having a ridge structure in its upper portion, formed on the active layer;
a first current blocking layer transparent to light generated from the active layer, formed at least on a side face of the ridge waveguide;
a second current blocking layer having light absorbency, formed on a flat portion of the cladding layer on each side of the ridge waveguide at a position spaced from the side face of the ridge waveguide, and
a third current blocking layer formed on the first current blocking layer and the second current blocking layer,
wherein
ηg>η1, ηg>η2, and ηg<η3 are satisfied where η1, η2, and η3 are respectively the heat expansion coefficients of the first, second, and third current blocking layers, and ηg is the heat expansion coefficient of gallium nitride.

2. The nitride semiconductor laser device of claim 1, wherein the first current blocking layer is not formed on a top portion of the side face of the ridge waveguide.

3. The nitride semiconductor laser device of claim 1, wherein Rf<Rr and A1f<A1r are satisfied where Rf and Rr are respectively the end facet reflectances on the front end facet side and rear end facet side of the cavity, and A1f and A1r are respectively the distances from the side face of the ridge waveguide to the second block layer at the front end facet and the rear end facet.

4. The nitride semiconductor laser device of claim 3, wherein Wf>Wr is satisfied where Wf and Wr are respectively the widths of the ridge waveguide on the front end facet side and rear end facet side of the cavity.

5. The nitride semiconductor laser device of claim 1, wherein the second current blocking layer is formed on the first current blocking layer.

6. The nitride semiconductor laser device of claim 1, wherein the second current blocking layer is formed on the cladding layer to be in contact with the cladding layer.

7. The nitride semiconductor laser device of claim 1, wherein the second current blocking layer is formed on at least one of cavity end facets formed at both ends of the ridge waveguide.
